(19) United States
(12) Patent Application Publication
(10) Pub. No.: US 2015/0221701 A1
(43) Pub. Date: Aug. 6, 2015

(54) MEMORY DEVICE AND MEMORY CELL ARRAY

(71) Applicant: Samsung Electronics Co., Ltd., Suwon-si (KR)

(72) Inventors: Min-kyu Yang, Hwaseong-Si (KR); Young-bae Kim, Seoul (KR); Hyun-sang Hwang, Pohang-si (KR); Ji-yong Woo, Pohang-si (KR)

(73) Assignee: Postech Academy-Industry Foundation, Pohang-si (KR)

(21) Appl. No.: 14/556,770

(22) Filed: Dec. 1, 2014

(30) Foreign Application Priority Data
Feb. 3, 2014 (KR) 10-2014-0012210

(51) Int. Cl. H01L 27/24; H01L 45/00

(52) U.S. Cl. CPC H01L 27/2463; H01L 45/1233; H01L 45/146; H01L 45/141

(57) ABSTRACT

A resistive memory device includes a stack of two layers of variable resistance material and top, middle, and bottom electrodes, the stack symmetrical in composition about the middle electrode.

### CROSS-REFERENCE TO RELATED APPLICATION

This application claims the benefit of Korean Patent Application No. 10-2014-0012210, filed on Feb. 3, 2014, in the Korean Intellectual Property Office, the disclosure of which is incorporated herein in its entirety by reference.

### BACKGROUND

Inventive concepts relate to a memory device and a memory cell array, and more particularly, to a resistive memory device and a resistive memory cell array.

Non-volatile memory devices include magnetic random access memory (MRAM), ferroelectric random access memory (FRAM), phase-change random access memory (PRAM), and resistive random access memory (RRAM). The RRAM is a non-volatile memory device that includes a material whose resistance changes significantly at a specified voltage. Resistive memory has a metal-insulator-metal (MIM) structure and manifests logic 0 or logic 1 by changing an insulating layer interposed between electrodes to be in a high resistance state (HRS) or to be in a low resistance state (LRS).

### SUMMARY

Example embodiments in accordance with principles of inventive concepts provide a resistive memory device and a resistive memory cell array that have a high on/off ratio while using low current in an off-state.

Example embodiments in accordance with principles of inventive concepts include a resistive memory device including a first electrode formed of a conductive material, a first variable resistance layer contacting the first electrode, a second electrode contacting the first variable resistance layer and formed of the conductive material, a second variable resistance layer contacting the second electrode and formed of the same material as that of the first variable resistance layer, and a third electrode contacting the second variable resistance layer and formed of the same material as that of the first electrode.

Example embodiments in accordance with principles of inventive concepts include a resistive memory device wherein the first variable resistance layer and the second variable resistance layer comprise metal oxide having non-stoichiometric composition.

Example embodiments in accordance with principles of inventive concepts include a resistive memory device wherein the first variable resistance layer and the second variable resistance layer comprise at least one of: nickel (Ni) oxide, titanium (Ti) doped Ni oxide, Ti oxide, hafnium (Hf) oxide, zirconium (Zr) oxide, niobium (Nb) oxide, aluminium (Al) oxide, vanadium (V) oxide, chromium (Cr) oxide, and tantalum (Ta) oxide.

Example embodiments in accordance with principles of inventive concepts include a resistive memory device wherein the first electrode and the third electrode are formed of ionizable metal.

Example embodiments in accordance with principles of inventive concepts include a resistive memory device wherein the second electrode is formed of inert metal.

Example embodiments in accordance with principles of inventive concepts include a resistive memory device wherein the first variable resistance layer and the second variable resistance layer are each configured to form a metal filament in response to application of a first voltage across the first and third electrodes.

Example embodiments in accordance with principles of inventive concepts include a resistive memory device wherein the thickness of each of the first variable resistance layer and the second variable resistance layer is from about 2 nm to about 20 nm.

Example embodiments in accordance with principles of inventive concepts include a resistive memory device wherein the first variable resistance layer and the second variable resistance layer are formed of an oxide of the metal forming the first electrode and the third electrode.

Example embodiments in accordance with principles of inventive concepts include a resistive memory device wherein the first variable resistance layer and the second variable resistance layer are formed of a chalcogenide electrolyte.

Example embodiments in accordance with principles of inventive concepts include a resistive memory cell array including a first bit line formed of a conductive material, a first variable resistance layer contacting the first bit line, a second electrode contacting the first variable resistance layer and formed of the conductive material, a second variable resistance layer contacting the second electrode and formed of the same material as that of the first variable resistance layer, and a first word line contacting the second variable resistance layer and formed of the same material as that of the first bit line.

Example embodiments in accordance with principles of inventive concepts include a resistive memory device array wherein the first variable resistance layer and the second variable resistance layer comprise metal oxide having non-stoichiometric composition.

Example embodiments in accordance with principles of inventive concepts include a resistive memory device array wherein the first electrode and the third electrode are formed of ionizable metal.

Example embodiments in accordance with principles of inventive concepts include a resistive memory device array wherein the second electrode is formed of inert metal.

Example embodiments in accordance with principles of inventive concepts include a resistive memory device array wherein the first variable resistance layer and the second variable resistance layer are formed of an oxide of the metal forming the first electrode and the third electrode.

Example embodiments in accordance with principles of inventive concepts include a resistive memory device array wherein the first variable resistance layer and the second variable resistance layer are formed of a chalcogenide electrolyte.

Example embodiments in accordance with principles of inventive concepts include a resistive memory cell including a stack of first and second layers of the same variable resistance material, first and second electrodes of the same conductive material respectively at the top and bottom of the variable resistance layers, and a third electrode between the first and second layers of variable resistance material, wherein a first voltage applied across the first and second electrodes places the first and second variable resistance layers in a high resistance state and a second voltage applied across the first and second electrodes places the variable resistance layers in a low resistance state.

Example embodiments in accordance with principles of inventive concepts include a resistive memory cell wherein the second voltage forms a conductive filament in each of the variable resistance layers.

Example embodiments in accordance with principles of inventive concepts include a resistive memory cell wherein the first voltage breaks a conductive filament in each of the variable resistance layers.

Example embodiments in accordance with principles of inventive concepts include a resistive memory cell wherein the variable resistance materials include transition metal oxides.

Example embodiments in accordance with principles of inventive concepts include a resistive memory cell wherein the variable resistance materials include a chalcogenide.

### BRIEF DESCRIPTION OF THE DRAWINGS

Exemplary embodiments of the inventive concept will be more clearly understood from the following detailed description taken in conjunction with the accompanying drawings in which:

FIG. 1 is a diagram illustrating a resistive memory cell array ;

FIG. 2 is a diagram illustrating a programmable metallization cell (PMC) resistive memory device;

FIG. 3 is a graph illustrating operations of the PMC resistive memory device of FIG. 2;

FIG. 4 is a diagram illustrating a resistive memory device according to example embodiments of inventive concepts;

FIG. 5 is a graph illustrating operations of a resistive memory device according to example embodiments of inventive concepts;

FIG. 6A is a diagram illustrating a resistive memory device according to example embodiments of inventive concepts;

FIG. 6B is a diagram illustrating a resistive memory device according to example embodiments of inventive concepts;

FIGS. 7A and 7B are diagrams illustrating resistive memory cell arrays including switching devices according to example embodiments of inventive concepts;

FIG. 8 is a diagram illustrating a resistive memory cell array according to example embodiments of inventive concepts;

FIG. 9 is a diagram illustrating a resistive memory cell array according to example embodiments of inventive concepts;

FIG. 10 is a block diagram illustrating a resistive memory system according to example embodiments of inventive concepts;

FIG. 11 is a diagram illustrating a resistive memory system according to example embodiments of inventive concepts;

FIG. 12 illustrates a computing system including a resistive memory device according to example embodiments of inventive concepts; and

FIG. 13 illustrates a memory card including a semiconductor device according to example embodiments of inventive concepts.

### DETAILED DESCRIPTION OF THE EMBODIMENTS

Various example embodiments will be described more fully hereinafter with reference to the accompanying drawings, in which some example embodiments are shown. Inventive concepts may, however, be embodied in many different forms and should not be construed as limited to the example embodiments set forth herein. Rather, these example embodiments are provided so that this description will be thorough and complete, and will convey the scope of inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items and the term “or” is meant to be inclusive, unless otherwise indicated.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of inventive concepts.
Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

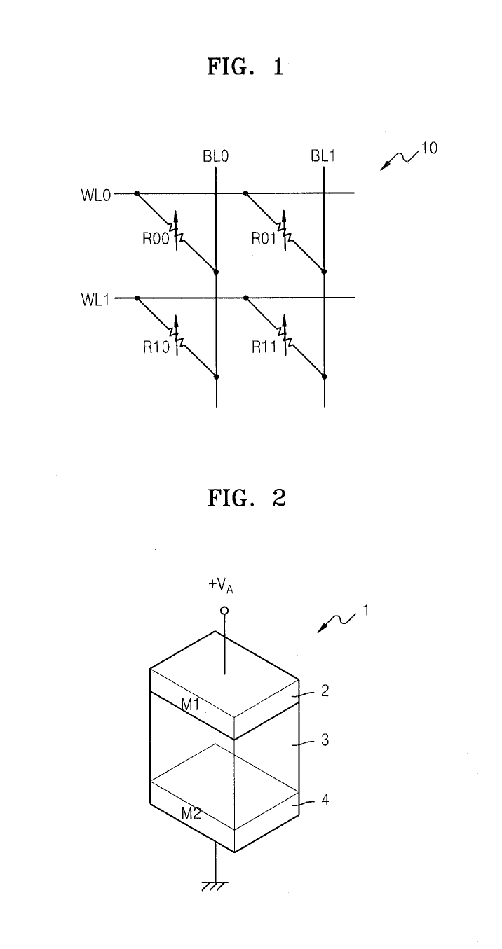

FIGS. 1 through 3 are diagrams illustrating structures and operations of a resistive memory device, also referred to herein as a programmable metallization cell (PMC) device.

FIG. 1 is a diagram illustrating a resistive memory cell array 10. Resistive memory cell array 10 may include a plurality of resistive memory devices R00, R01, R10, and R11. Resistance of the resistive memory devices R00, R01, R10, and R11 may change according to voltages that are applied to word lines WL0 and WL1, and bit lines BL0 and BL1.

For example, in a program operation (also referred to herein as a “write operation,” or “set operation”), by applying a first voltage V1 to the bit line BL1 and applying a second voltage V2 to the word line WL1, the difference between the first voltage V1 and the second voltage V2, that is, V1-V2, may be applied to the resistive memory device R11. If the difference between the first voltage V1 and the second voltage V2, that is, V1-V2, is applied to the resistive memory device R11, resistance of the resistive memory device R11 may change.

If the resistive memory device R11 is in a low resistance state (LRS), data stored in the resistive memory device R11 may be referred to as a logic 1, and if the resistive memory device R11 is in a high resistance state (HRS), data stored in the resistive memory device R11 may be referred to as a logic 0. In a read operation, a current flowing in the bit line BL1 may be detected by applying a third voltage V3 to the word line WL1, and data corresponding to the resistive memory device R11 may be determined as 1 or 0 according to the amount of current flowing in the resistive memory device R11. For example, if the amount of current flowing in the resistive memory device R11 is large, data corresponding to the resistive memory device R11 may be a logic 1 (corresponding to a low resistance state). If the amount of current flowing in the resistive memory device R11 is small, data corresponding to the resistive memory device R11 may be a logic 0 (corresponding to a high resistance state).

In a reset operation, by applying a fourth voltage V4 to the bit lines BL0 and BL1 and applying a fifth voltage V5 to the word lines WL0 and WL1, the difference between the forth voltage V4 and the fifth voltage V5, that is, V4-V5, may be applied to the resistive memory devices R00, R01, R10, and R11 to change their resistance to a certain value. For example, data stored in the resistive memory devices R00, R01, R10, and R11, where the reset operation has been performed, may be a logic 0.

FIG. 2 is a diagram illustrating a programmable metallization cell (PMC) resistive memory device 1. The PMC resistive memory device 1 may include a first electrode 2, a second electrode 4, and a variable resistance layer 3.

The first electrode 2 and the second electrode 4 may include, for example, a conductive material, such as may be used for an electrode of a semiconductor device. The first electrode 2 and the second electrode 4 may include ionizable metal. The first electrode 2 and second electrode 4 may include metal, for example, copper (Cu) or silver (Ag).

The second electrode 4 may include, for example, inert metal. The second electrode 4 may include metal, for example, tungsten (W), titanium nitride (TiN), or platinum (Pt).

The variable resistance layer 3 may include a variable resistance material used for a resistive memory device, such as a perovskite, transition metal oxide, or chalcogenide, for example.

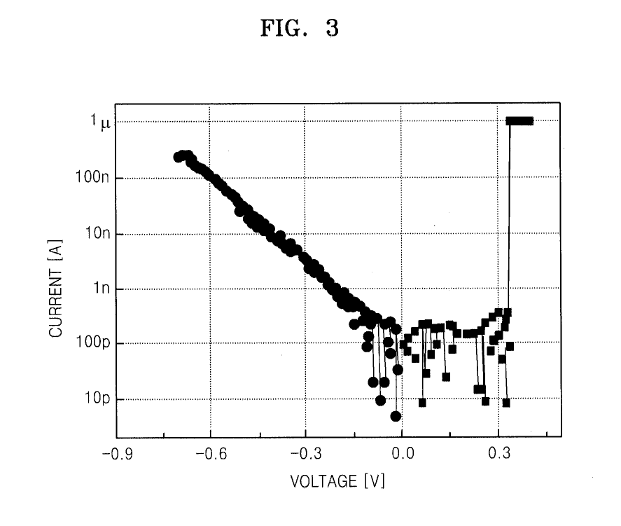

Voltage/current operation of memory device 1 is illustrated in FIG. 3. If about −0.5V is applied to the first electrode 2 of the resistive memory device 1 and about 0V is applied to the second electrode 4, a current of about 10 nA (nanoampere) may flow in the resistive memory device 1. This low current level corresponds to a high resistance state, a RESET state, which is also referred to herein as a logic 0 state. A reset or erase operation may be performed by using this characteristic of the resistive memory device 1.

If about +0.5V is applied to the first electrode 2 of the resistive memory device 1 and about 0V is applied to the second electrode 4, a current of about 1 uA (microampere) may flow in the resistive memory device 1. In this case, one in which the polarity of applied voltage is switched, the relatively high current corresponds to a low resistance state, a SET state, which is also referred to herein as a logic 1 state. A set, program, or write operation may be performed by using this characteristic of the resistive memory device 1.

If about 0V is applied to the first electrode 2 of the resistive memory device 1 and about 0V is applied to the second electrode 4, a current of about 1 pA (picoampere) may flow in the resistive memory device 1.

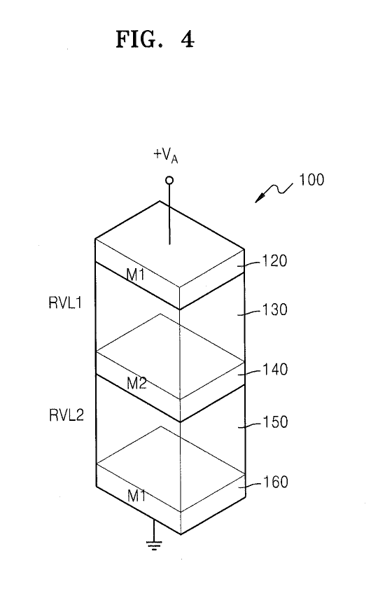

FIG. 4 is a diagram of an example embodiment of a resistive memory device 100 in accordance with principles of inventive concepts. Resistive memory devices R00, R01, R10, and R11 include a first electrode, a third electrode, a first variable resistance material, and a second variable resistance material in a symmetric structure (and a second electrode). In exemplary embodiments, a high on/off resistance ratio is obtained, while minimizing off-state current. In example embodiments in accordance with principles of inventive concepts, resistive memory device 100 may include a first electrode 120, a second electrode 140, a third electrode 160, a first variable resistance layer 130, and a second variable resistance layer 150.

The first electrode 120, the second electrode 140, and the third electrode 160 may include, for example, a conductive material, such as may be used for an electrode of a semiconductor device.

The first electrode 120 and the third electrode 160 may include ionizable metal. The first electrode 120 and the third electrode 160 may include metal, for example Cu or Ag and may be formed using the same material according to an example embodiment in accordance with principles of inventive concepts.

The second electrode 140 may include, for example, inert metal. The second electrode 140 may include metal, for example W, TiN, or Pt.

The first variable resistance layer 130 and the second variable resistance layer 150 may be formed by using a variable resistance material used for a resistive memory device. The variable resistance material may be a variable resistance material such as a perovskite, transition metal oxide, or chalcogenide, for example. In example embodiments, the variable resistance material has more than two resistance characteristics (also referred to herein as resistance states) according to applied voltage. For example, the variable resistance material may have four resistance states, according to the level of an applied voltage and may be implemented as a multi-level cell (MLC). The first variable resistance layer 130 and the second variable resistance layer 150 of the resistive memory device 100 may be formed by using the same material in example embodiments in accordance with principles of inventive concepts.

Not wishing to be bound by theory, it is believed that, in example embodiments in accordance with principles of inventive concepts, the first variable resistance layer 130 and the second variable resistance layer 150 of the resistive memory device 100 may adjust the thickness of a conductive filament formed by the applied voltage, by adjusting oxygen concentration of an oxide film. The first variable resistance layer 130 and the second variable resistance layer 150 of the resistive memory device 100 may control the size of changed voltage by adjusting the oxygen concentration of the oxide film and adjusting the thickness of the filament.

According to example embodiments of inventive concepts, the first electrode 120 and the third electrode 160 of the resistive memory device 100 are formed of the same material, and the first variable resistance layer 130 and the second variable resistance layer 150 are formed of the same material. In this manner, in example embodiments, the resistive memory device 100 may have a symmetric structure.

When a first voltage is applied between the first electrode 120 and the third electrode 160, the first variable resistance layer 130 and the second variable resistance layer 150 may form a metal filament(s). In example embodiments, the thicknesses of the first variable resistance layer 130 and of the second variable resistance layer 150 may be from about 2 nm to about 20 nm.

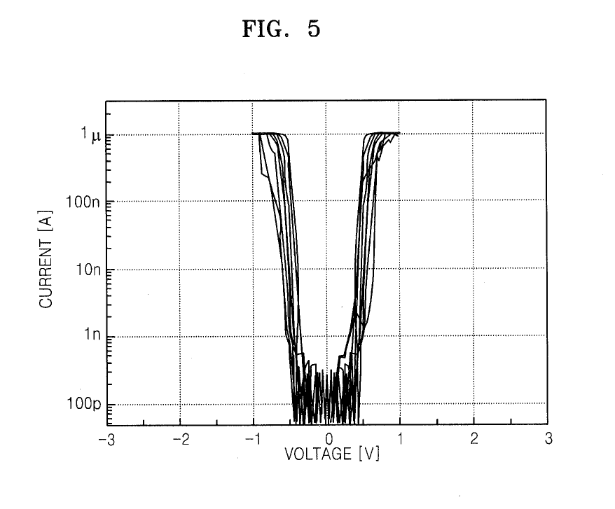

FIG. 5 is a graph illustrating operation of resistive memory device 100 according to example embodiments of inventive concepts. In an example embodiment, if a voltage of about −0.5V is applied to the first electrode 120 of the resistive memory device 100 and about 0V is applied to the third electrode 160, a current of about 100 pA (picoampere) may flow in the resistive memory device 100. In this case, the low current level indicates high resistance and a RESET, or logic 0 state, data stored in the memory device 100 may be a logic 0. A reset or erase operation may be performed by using this characteristic of the resistive memory device 100.

In an example embodiment, if about 1V is applied to the first electrode 120 of the resistive memory device 100 and about 0V is applied to the third electrode 160, a current of about 1 uA (microampere) may flow in the resistive memory device 100. In this case, data stored in the memory device 100 may be a logic 1. A set, program, or write operation may be performed by using this characteristic of the device.

In an example embodiment, if about 0V is applied to the first electrode 120 of the resistive memory device 100 and about 0V is applied to the third electrode 160, a current of about 100 pA (picoampere) may flow in the resistive memory device 100. In this case, data stored in the memory device 100 may be mapped as 0. A set, program, or write operation may be performed by using this characteristic of the device.

Even in the case where the reset or erase operation is performed, the resistive memory device 100 that has been described in FIGS. 4 and 5 has a current flowing in a low state, compared to the case of the PMC resistive memory device described in FIGS. 2 and 3. Accordingly, the resistive memory device 100 according to example embodiments of inventive concepts may have a high on/off ratio while using a current in a low off state.

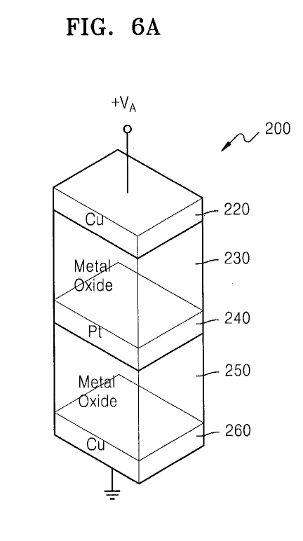

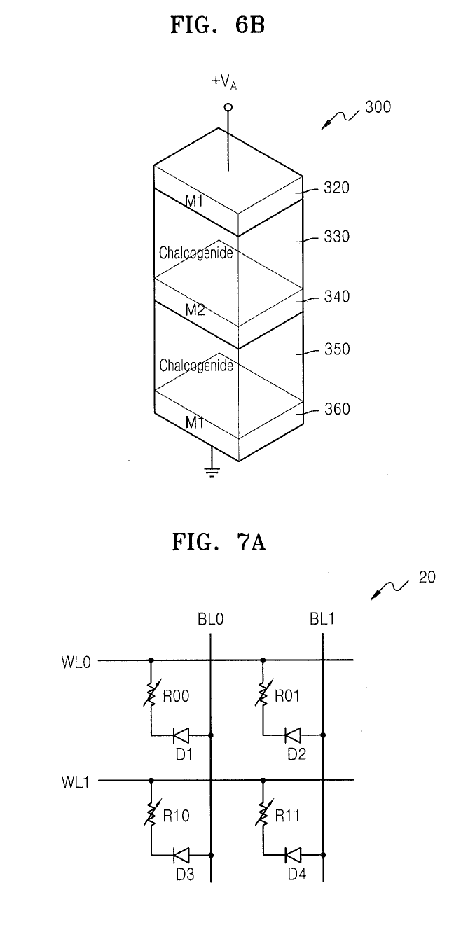

FIG. 6A is a diagram illustrating a resistive memory device 200 according to example embodiments of inventive concepts.

Referring to FIG. 6A, the resistive memory device 200 may include a first electrode 220, a second electrode 240, a third electrode 260, a first variable resistance layer 230, and a second variable resistance layer 250.

The first electrode 220 and the third electrode 260 may include ionizable metal. The first electrode 220 and the third electrode 260 may include metal, for example, Cu or Ag. The second electrode 240 may include, for example, inert metal. The second electrode 240 may include metal, for example, W, TiN, or Pt.

The first variable resistance layer 230 and the second variable resistance layer 250 may be formed of a variable resistance material used for a resistive memory device. The variable resistance material may be a variable resistance material such as a perovskite, transition metal oxide, or chalcogenide, for example. The first variable resistance layer 230 and the second variable resistance layer 250 may include non-stoichiometric metal oxide. For example, the first variable resistance layer 230 and the second variable resistance layer 250 may use transition metal oxide as well as nickel (Ni) oxide, titanium (Ti) doped Ni oxide, Ti oxide, hafnium (Hf) oxide, zirconium (Zr) oxide, niobium (Nb) oxide, aluminium (Al) oxide, vanadium (V) oxide, chromium (Cr) oxide, and tantalum (Ta) oxide.

The first variable resistance layer 230 and the second variable resistance layer 250 of the resistive memory device 200 according to example embodiments of inventive concepts may be formed of oxide obtained from a material of the first electrode 220 and the third electrode 260. For example, the first variable resistance layer 230 and the second variable resistance layer 250 of the resistive memory device 200 may be formed of oxide of Cu or Ag, and the first electrode 220 and the third electrode 260 may be formed of Cu or Ag.

According to example embodiments of inventive concepts, the first electrode 220 and the third electrode 260 of the resistive memory device 200 are formed of the same material, and the first variable resistance layer 230 and the second variable resistance layer 250 are formed of the same material. Thus, the resistive memory device 200 may have a symmetric structure.

FIG. 6B is a diagram illustrating a resistive memory device 300 according to example embodiments of inventive concepts.

Referring to FIG. 6B, the resistive memory device 300 may include a first electrode 320, a second electrode 340, a third electrode 360, a first variable resistance layer 330, and a second variable resistance layer 350.

The first electrode 320 and the third electrode 360 may include ionizable metal. The first electrode 320 and the third electrode 360 may include metal, for example, Cu or Ag. The second electrode 340 may include, for example, inert metal. The second electrode 340 may include metal, for example W, TiN, or Pt.

According to example embodiments of inventive concepts, the first variable resistance layer 330 and the second variable resistance layer 350 of the resistive memory device 300 may be formed of a chalcogenide electrolyte.

According to example embodiments of inventive concepts, the first electrode 320 and the third electrode 360 of the resistive memory device 300 are formed of the same material, and the first variable resistance layer 330 and the second variable resistance layer 350 are formed of the same material. Thus, the resistive memory device 300 may have a symmetric structure.

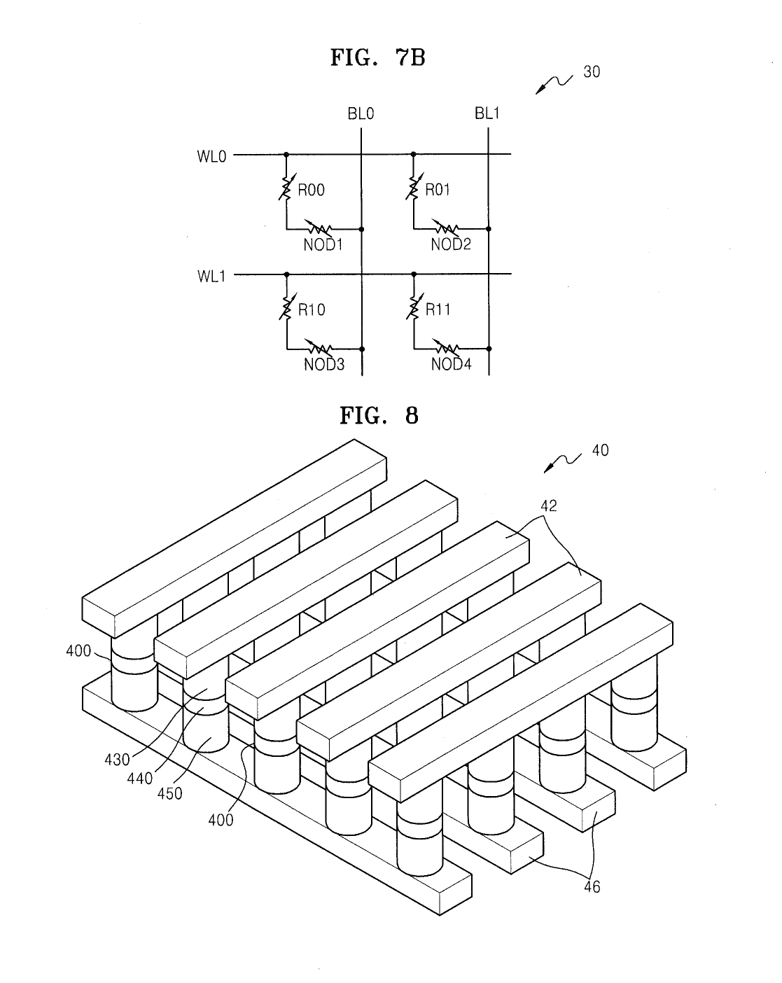

FIGS. 7A and 7B are diagrams illustrating resistive memory cell arrays 20 and 30 including switching devices according to example embodiments of inventive concepts.

Referring to FIG. 7A, the resistive memory cell array 20 may include a plurality of resistive memory devices R00, R01, R10, and R11. The resistive memory devices R00, R01, R10, and R11 of the resistive memory cell array 20 may be connected to diodes D1, D2, D3, and D4, respectively. Each of the diodes D1, D2, D3, and D4 may prevent current “sneak paths” by controlling current direction.

Referring to FIG. 7B, the resistive memory cell array 30 may include a plurality of the resistive memory devices R00, R01, R10, and R11. The resistive memory devices R00, R01, R10, and R11 of the resistive memory cell array 30 may be connected to non-ohmic devices NOD1, NOD2, NOD3, and NOD4, respectively. The non-ohmic devices may include, for example, nonlinear devices. The non-ohmic devices may include, for example, variable resistors. Accordingly, a current may be increased in a specific direction needed for an operation by controlling the resistance of the non-ohmic devices.

FIG. 8 is a diagram illustrating a resistive memory cell array 40 according to example embodiments of inventive concepts.

The resistive memory cell array 40 may include a plurality of resistive memory devices 400 between bit lines 42 and word lines 46.

Each of the plurality of the resistive memory devices 400 may include a second electrode 440. The second electrode 440 may include, for example, inert metal.

The bit lines 42 and the word lines 46 may include the same metal. In addition, a first variable resistance layer 430 and a second variable resistance layer 450 may be formed of the same material. The plurality of resistive memory devices 400 may operate as illustrated in the graph of FIG. 5, respectively.

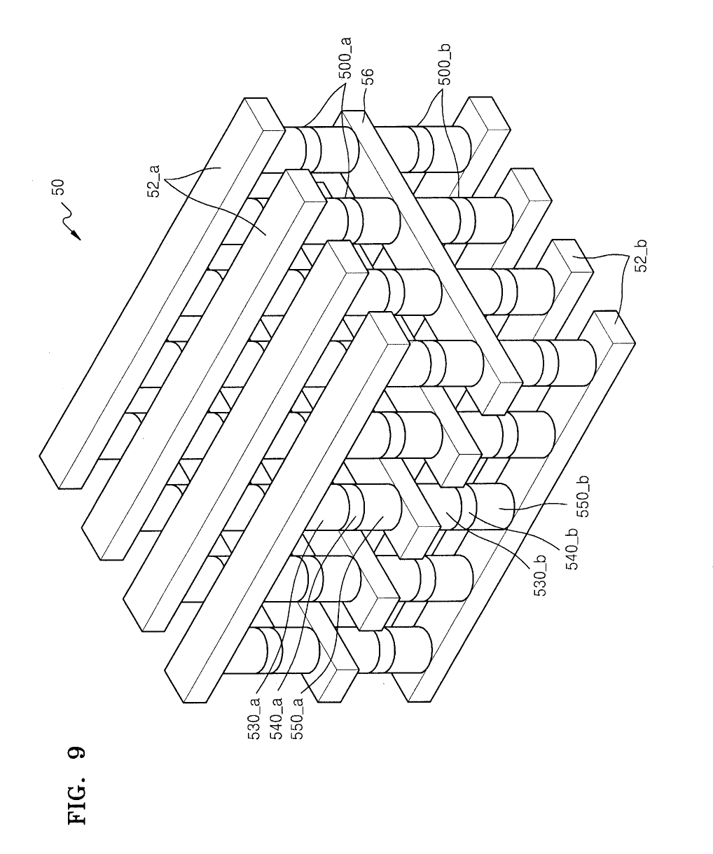

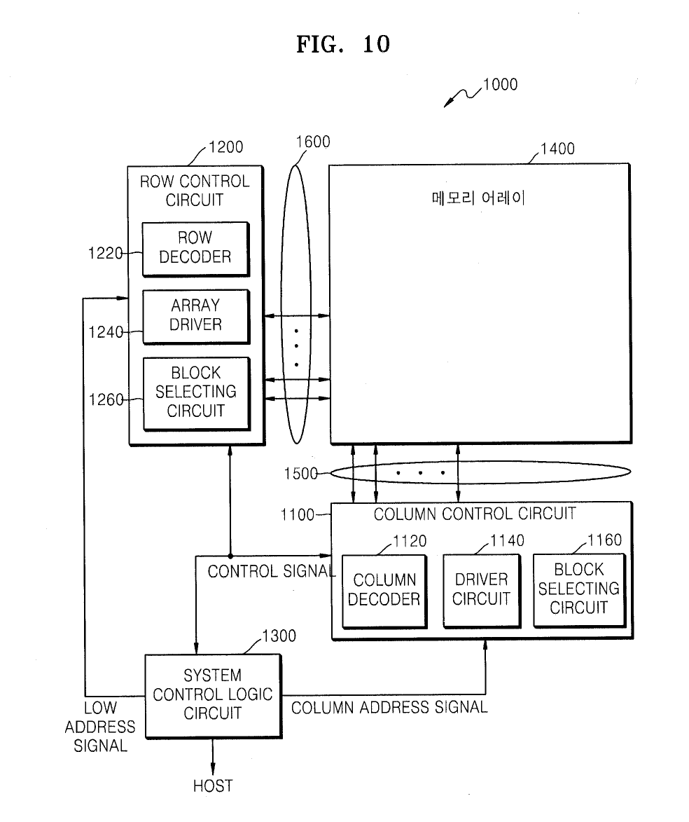

FIG. 9 is a diagram illustrating a resistive memory cell array 50 according to example embodiments of inventive concepts.

The resistive memory cell array 50 may include a plurality of resistive memory devices 500_{—}a and 500_{—}b between bit lines 52_{—}a and 52_{—}b and a word line 56.

Each of the plurality of the resistive memory devices 500_{—}a and 500_{—}b may include second electrodes 540_{—}a and 540_{—}b. The second electrodes 540_{—}a and 540_{—}b may include, for example, inert metal.

The bit lines 52_{—}a and 52_{—}b and the word line 56 may include the same metal. In addition, first variable resistance layers 530_{—}a and 530_{—}b and second variable resistance layers 550_{—}a and 550_{—}b may include the same material. The plurality of the resistive memory devices 500_{—}a and 500_{—}b may operate as illustrated in the graph of FIG. 5, respectively.

FIG. 10 is a diagram illustrating a resistive memory system 1000 according to example embodiments of inventive concepts.

The resistive memory system 1000 may include a memory array 1400. Resistive memory devices of the memory array 1400 may include at least one semiconductor device from among the resistive memory devices manufactured by using the structures illustrated in FIGS. 4, 6A, and 6B.

The resistive memory system 1000 may include a row control circuit 1200. Inputs/outputs 1600 of the row control circuit 1200 may be connected to respective word lines of the memory array 1400. In example embodiments, row control circuit 1200 receives a group of M row address signals and one or more various control signals from a system control logic circuit 1300. The row control circuit 1200 may also include circuits such as a row decoder 1220, an array driver 1240, and a block selecting circuit 1260 for set and reset operations.

The resistive memory system 1000 may include a column control circuit 1100. Inputs/outputs 1500 of the column control circuit 1100 may be connected to respective bit lines of the memory array 1400. The column control circuit 1100 may receive a group of N row address signals and one or more various control signals from the system control logic circuit 1300. The column control circuit 1100 may commonly include a column decoder 1120, an array terminal receiver or a driver circuit 1140, and a block selecting circuit 1160. The column control circuit 1100 may include a read/write circuit including a sense amplifier (not shown) and an I/O multiplexer (not shown).

In example embodiments, system control logic circuit 1300 receives commands and data from a host (for example, an application processor) and provides output data to the host. In another embodiment, the system control logic circuit 1300 receives commands and data from a separate controller circuit and provides output data to the controller circuit, which may correspond with the host. The system control logic circuit 1300 may include one or more state machines and registers and may also include another control logic for controlling the resistive memory system 1000.

In example embodiments, all components illustrated in FIG. 10 may be arranged on one integrated circuit. For example, the system control logic circuit 1300, the column control circuit 1100, and the row control circuit 1200 may be formed on an upper surface of a substrate. In addition, the memory array 1400, which may be a monolithic three-dimensional memory array, may be formed on the substrate (on the system control logic circuit 1300, the column control circuit 1100, and the row control circuit 1200). Some of the control circuit may be also formed on the same layers as some of the memory array 1400.

An integrated circuit memory array commonly divides a memory array into several sub-arrays or blocks. The blocks may be also grouped together as bays, and the bays include blocks as many as 16, 32, or other number. As frequently used, the sub-arrays are a consecutive group of memory cells and have consecutive word lines and bit lines that are not commonly divided by decoders, drivers, sense amplifiers, and input/output circuits.

The above described operations are performed for various reasons. For example, signal delays (that is, RC delays) of word lines and bit lines caused by resistance and capacitance of the word lines and bit lines may be serious for a large-scale array. These RC delays may be decreased by dividing the big array into a group of small sub-arrays so as to decrease the length of each word line and/or each bit line. As another example, power that is related with accessing the group of memory cells may determine an upper limit for the number of memory cells that may concurrently access during a given memory cycle. As a result, a large memory array is often divided into small sub-arrays so as to decrease the number of memory cells that access concurrently.

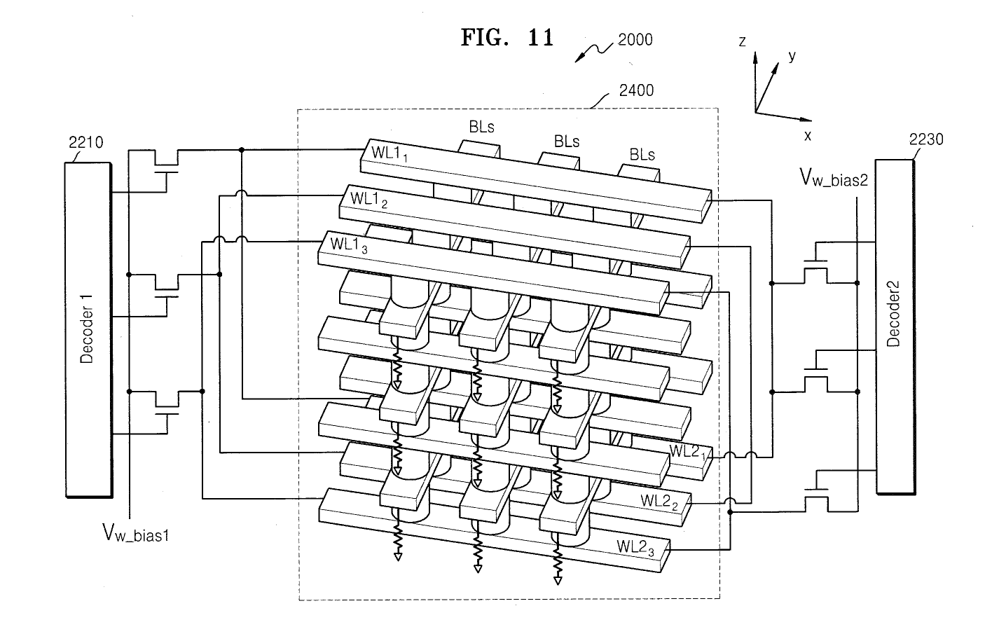

FIG. 11 is a diagram illustrating a resistive memory system 2000 according to example embodiments in accordance to principles of inventive concepts.

The resistive memory system 2000 may include a resistive memory array 2400. The resistance memory array 2400 may be a three-dimensional array similar to the array of FIG. 9. In an embodiment, the resistive memory array 2400 may be a monolithic three-dimensional memory array, for example. Array terminal lines of the resistive memory array 2400 may include various layers of word lines, which are composed of rows, and various layers of bit lines, which are composed of columns. The word lines of the resistive memory array 2400 may control an operation of resistive memories that are connected to decoders 2210 and 2230 and are included in the resistive memory array 2400.

Resistive memory devices included in the resistive memory array 2400 of various exemplary embodiments of the present disclosure may include at least one semiconductor device from among the resistive memory devices manufactured by using the structures illustrated in FIGS. 4, 6A, and 6B. The three-dimensional array was divided into 6 layers in FIG. 11, but inventive concepts are not limited thereto.

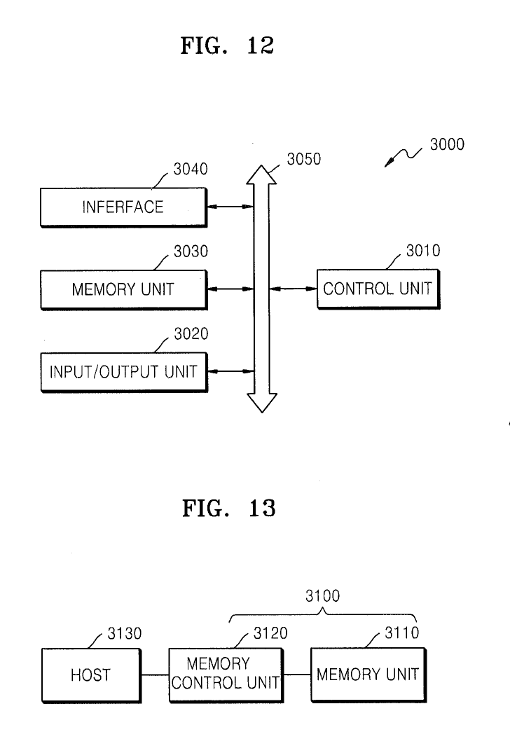

FIG. 12 illustrates a computing system 3000 including a resistive memory device according to example embodiments of inventive concepts.

Referring to FIG. 12, the computing system 3000 according to example embodiments of inventive concepts may include a control unit 3010, an input/output unit 3020, a memory unit 3030, and an interface 3040. The computing system 3000 may be a mobile system or a system that sends and receives information. In an embodiment, the computing system 3000 may be a personal digital assistant (PDA), a portable computer, a web tablet, a wireless phone, a mobile phone, a digital music player, or a memory card.

The control unit 3010 controls an executable program of the computing system 3000 and may be formed of a microprocessor, a digital signal processor, a microcontroller, or the like.

The input/output unit 3020 may be used to input or output data of the computing system 3000. The computing system 3000 may be connected to an external device, for example, a personal computer or network, by using the input/output unit 3020, and may mutually exchange data with the external device. The input/output unit 3020 may be, for example, a keypad, a keyboard, or a display.

The memory unit 3030 may store a code and/or data for operating the control unit 3010, or may store data processed by the control unit 3010. The memory unit 3030 may include the resistive memory device according to a technical spirit of the inventive concept. For example, the memory unit 3030 may include at least one semiconductor device from among the resistive memory devices manufactured by using the structures illustrated in FIGS. 4, 6A, and 6B.

The interface 3040 may be a data transmission passage between the computing system 3000 and the external device. The control unit 3010, the input/output unit 3020, the memory unit 3030, and the interface 3040 may communicate with one another through a bus 3050.

The computing system 3000 according to the present embodiment may be used for, for example, mobile phones, MP3 players, navigations, portable multimedia players (PMPs), solid state disks (SSDs), or household appliances.

FIG. 13 illustrates a memory card 3100 including a semiconductor device according to example embodiments of inventive concepts.

Referring to FIG. 13, memory card 3100 according to example embodiments may include a memory unit 3110 and a memory control unit 3120.

The memory unit 3110 may store data. In embodiments, the memory unit 3110 may have a non-volatile property of keeping stored data even when not powered. The memory unit 3110 may include at least one semiconductor device from among the resistive memory devices manufactured using the structures illustrated in FIGS. 4, 6A, and 6B.

The memory control unit 3120 may read data stored in the memory unit 3110 or may store data in the memory unit 3110 in response to a read or write command from a host 3130. The memory control unit 3120 may include at least one semiconductor device from among the resistive memory devices manufactured by using the structures illustrated in FIGS. 4, 6A, and 6B.

While inventive concepts have been particularly shown and described with reference to exemplary embodiments thereof, it will be understood that various changes in form and details may be made therein without departing from the spirit and scope of the following claims.

What is claimed is:

1. A resistive memory device comprising:
a first electrode formed of a conductive material;
a first variable resistance layer contacting the first electrode;
a second electrode contacting the first variable resistance layer and formed of the conductive material;
a second variable resistance layer contacting the second electrode and formed of the same material as that of the first variable resistance layer; and
a third electrode contacting the second variable resistance layer and formed of the same material as that of the first electrode.

2. The resistive memory device of claim 1, wherein the first variable resistance layer and the second variable resistance layer comprise metal oxide having non-stoichiometric composition.

3. The resistive memory device of claim 1, wherein the first variable resistance layer and the second variable resistance layer comprise at least one of: nickel (Ni) oxide, titanium (Ti) doped Ni oxide, Ti oxide, hafnium (Hf) oxide, zirconium (Zr) oxide, niobium (Nb) oxide, aluminium (Al) oxide, vanadium (V) oxide, chromium (Cr) oxide, and tantalum (Ta) oxide.

4. The resistive memory device of claim 1, wherein the first electrode and the third electrode are formed of ionizable metal.

5. The resistive memory device of claim 1, wherein the second electrode is formed of inert metal.

6. The resistive memory device of claim 1, wherein the first variable resistance layer and the second variable resistance layer are each configured to form a metal filament in response to application of a first voltage across the first and third electrodes.

7. The resistive memory device of claim 1, wherein the thickness of each of the first variable resistance layer and the second variable resistance layer is from about 2 nm to about 20 nm.

8. The resistive memory device of claim 1, wherein the first variable resistance layer and the second variable resistance layer are formed of an oxide of the metal forming the first electrode and the third electrode.

9. The resistive memory device of claim 1, wherein the first variable resistance layer and the second variable resistance layer are formed of a chalcogenide electrolyte.

10. A resistive memory cell array comprising:
a first bit line formed of a conductive material;
a first variable resistance layer contacting the first bit line;
a second electrode contacting the first variable resistance layer and formed of the conductive material;
a second variable resistance layer contacting the second electrode and formed of the same material as that of the first variable resistance layer; and
a first word line contacting the second variable resistance layer and formed of the same material as that of the first bit line.

11. The resistive memory cell array of claim 10, wherein the first variable resistance layer and the second variable resistance layer comprise metal oxide having non-stoichiometric composition.

12. The resistive memory cell array of claim 10, wherein the first electrode and the third electrode are formed of ionizable metal.

13. The resistive memory cell array of claim 10, wherein the second electrode is formed of inert metal.

14. The resistive memory cell array of claim 10, wherein the first variable resistance layer and the second variable resistance layer are formed of an oxide of the metal forming the first electrode and the third electrode.

15. The resistive memory cell array of claim 10, wherein the first variable resistance layer and the second variable resistance layer are formed of a chalcogenide electrolyte.

16. A resistance memory cell, comprising:
a stack of first and second layers of the same variable resistance material;
first and second electrodes of the same conductive material respectively at the top and bottom of the variable resistance layers; and
a third electrode between the first and second layers of variable resistance material, wherein a first voltage applied across the first and second electrodes places the first and second variable resistance layers in a high resistance state and a second voltage applied across the first and second electrodes places the variable resistance layers in a low resistance state.

17. The resistance memory cell of claim 16, wherein the second voltage forms a conductive filament in each of the variable resistance layers.

18. The resistance memory cell of claim 16, wherein the first voltage breaks a conductive filament in each of the variable resistance layers.

19. The resistance memory cell of claim 16, wherein the variable resistance materials include transition metal oxides.

20. The resistance memory cell of claim 16, wherein the variable resistance materials include a chalcogenide.
